(19) United States
(12) Patent Application Publication
(10) Pub. No.: US 2026/0052882 A1
(43) Pub. Date: Feb. 19, 2026

(54) DISPLAY PANEL, METHOD FOR PREPARING DISPLAY PANEL, AND ELECTRONIC DEVICE

(71) Applicants: KunShan Go-Visionox Opto-Electronics Co., Ltd., Kunshan (CN); Hefei Visionox Technology Co., Ltd., Hefei (CN)

(72) Inventors: Zhen FU, Hefei (CN); Xu QIAN, Hefei (CN); Ying SHEN, Kunshan (CN); Shuangbing ZHANG, Hefei (CN)

(73) Assignees: KunShan Go-Visionox Opto-Electronics Co., Ltd., Kunshan (CN); Hefei Visionox Technology Co., Ltd., Hefei (CN)

(21) Appl. No.: 19/313,748

(22) Filed: Aug. 28, 2025

(30) Foreign Application Priority Data
Jun. 28, 2024 (CN) 202410865293.3

(51) Int. Cl. H10K 59/80; H10K 59/12; H10K 59/122; H10K 59/32; H10K 59/40; H10K 102/00

(52) U.S. Cl. CPC H10K 59/8723; H10K 59/1201; H10K 59/122; H10K 59/32; H10K 59/40; H10K 59/873; H10K 2102/351

(57) ABSTRACT

Embodiments of the present application provide a display panel, a method for preparing the display panel, and an electronic device, which relate to the field of display technology. The display panel includes an array substrate and an isolation structure. The isolation structure is located on one side of the array substrate and encloses to form an isolation opening. The isolation structure includes a conductive portion and an isolation portion sequentially stacked in a direction away from the array substrate. The isolation portion includes a recessed portion that is recessed in a direction away from the isolation opening. By providing the recessed portion on the isolation portion that is recessed in the direction away from the isolation opening, the present application can improve the continuity and thickness of the inorganic encapsulation layer at the contact area with the isolation structure, thereby enhancing the encapsulation effect of the inorganic encapsulation layer and further improving the display performance of the display panel.

### CROSS-REFERENCE TO RELATED APPLICATIONS

This application claims priority to Chinese Patent Application No. 202410865293.3, filed on Jun. 28, 2024, which is incorporated herein by reference in its entirety.

### TECHNICAL FIELD

The present application relates to the technical field of display, and in particular to a display panel, a method for preparing a display panel, and an electronic device.

### BACKGROUND

Organic light emitting diodes (OLEDs) and flat panel display devices based on technologies such as light emitting diodes (LEDs) have been widely applied to various consumer electronics such as mobile phones, televisions, notebook computers and desktop computers and predominate in display panels thanks to their advantages such as high image quality, energy efficiency, slim design and a wide range of applications.

However, the display panels still have some issues that need to be urgently addressed.

### SUMMARY

In order to overcome the technical problems mentioned in the above background art, embodiments of the present application provide a display panel. The display panel includes:
an array substrate; and
an isolation structure located on a side of the array substrate, the isolation structure enclosing isolation openings, and the isolation structure including a conductive portion and an isolation portion which are sequentially stacked in a direction away from the array substrate, and the isolation portion including a recess that is recessed in a direction away from the isolation opening.

In some possible implementations, in a cross section in a direction perpendicular to the array substrate, a dimension of the second isolation portion gradually increases in the direction away from the array substrate.

In some possible implementations, in the cross section in the direction perpendicular to the array substrate, a side of the second isolation portion facing the isolation opening includes at least one of a straight section and a curved section.

In some possible implementations, in the cross section in the direction perpendicular to the array substrate, the second isolation portion has an inverted trapezoid cross section.

In some possible implementations, in the cross section in the direction perpendicular to the array substrate, a side of the second isolation portion facing the isolation opening is curved.

In some possible implementations, in a cross section in a direction perpendicular to the array substrate, a dimension of the first isolation portion is gradually reduced in the direction away from the array substrate.

In some possible implementations, in the cross section in the direction perpendicular to the array substrate, a side of the first isolation portion facing the isolation opening includes at least one of a straight section and a curved section.

In some possible implementations, in the cross section in the direction perpendicular to the array substrate, the first isolation portion has a trapezoid cross section.

In some possible implementations, in the cross section in the direction perpendicular to the array substrate, a side of the first isolation portion facing the isolation opening is curved.

In some possible implementations, an included angle between the side of the first isolation portion facing the isolation opening and a side of the second isolation portion facing the isolation opening is an obtuse angle.

In some possible implementations, an included angle between the side of the first isolation portion facing the isolation opening and a side of the second isolation portion facing the isolation opening ranges from 105° to 135°.

In some possible implementations, the isolation structure further includes a blocking portion on the side of the isolation portion away from the array substrate, and an orthographic projection of the blocking portion on the array substrate at least partially coincides with the orthographic projection of the isolation portion on the array substrate.

Preferably, the orthographic projection of the side of the isolation portion away from the array substrate on the array substrate is located within the orthographic projection of the blocking portion on the array substrate.

In some possible implementations, the present application further provides a method for preparing a display panel, the method including:
providing an array substrate; and
forming an isolation structure on a side of the array substrate, the isolation structure enclosing isolation openings, and the isolation structure including a conductive portion and an isolation portion which are sequentially stacked in a direction away from the array substrate, and the isolation portion including a recess that is recessed in a direction away from the isolation opening.

In some possible implementations, the present application further provides an electronic device, including a display panel according to the present application, or a display panel prepared by the method for preparing the display panel according to the present application.

The present application has the following beneficial effects with respect to the prior art.

The present application provides a display panel, a method for preparing a display panel, and an electronic device. The recess that is recessed in the direction away from the isolation opening is provided in the isolation portion such that it is possible to make the inorganic encapsulation layer at the contact with the isolation structure more continuous and thicker, thereby improving the encapsulation effect of the inorganic encapsulation layer, which can in turn improve the display effect of the display panel.

### BRIEF DESCRIPTION OF THE DRAWINGS

In order to illustrate the technical solutions of embodiments of the present application more clearly, the drawings required in the embodiments will be briefly introduced below. It should be understood that the following drawings only show some embodiments of the present application, and therefore should not be construed as a limitation on the scope. For those of ordinary skill in the art, other related drawings can be obtained from these drawings without involving any inventive effort.

FIG. 1 is a first schematic cross-sectional view of a display panel according to an embodiment of the present application;

FIG. 2 is a second schematic cross-sectional view of a display panel according to an embodiment of the present application;

FIG. 3 is a third schematic cross-sectional view of a display panel according to an embodiment of the present application;

FIG. 4 is a fourth schematic cross-sectional view of a display panel according to an embodiment of the present application;

FIG. 5 is a schematic cross-sectional view of an isolation structure according to an embodiment of the present application further including a blocking portion;

FIG. 6 is a schematic cross-sectional view of a display panel according to an embodiment of the present application including light-emitting units;

FIG. 7 is a schematic cross-sectional view of a light-emitting functional layer according to an embodiment of the present application;

FIG. 8 is a schematic cross-sectional view of two superimposed light-emitting functional layers according to an embodiment of the present application;

FIG. 9 is a first schematic cross-sectional view of a display panel according to an embodiment of the present application including a first encapsulation layer;

FIG. 10 is a graph of a film thickness of the first encapsulation layer as function of a maximum stress according to an embodiment of the present application;

FIG. 11 is a second schematic cross-sectional view of a display panel according to an embodiment of the present application including a first encapsulation layer;

FIG. 12 is a schematic cross-sectional view of a display panel according to an embodiment of the present application including a second encapsulation layer and a third encapsulation layer;

FIG. 13 is a first schematic cross-sectional view of a display panel according to an embodiment of the present application including a filter layer;

FIG. 14 is a second schematic cross-sectional view of a display panel according to an embodiment of the present application including a filter layer;

FIG. 15 is a schematic cross-sectional view of a display panel according to an embodiment of the present application including touch electrodes;

FIG. 16 is a schematic cross-sectional view of a display panel according to an embodiment of the present application including touch layers;

FIG. 17 is a schematic top view of a display panel according to an embodiment of the present application;

FIG. 18 is a schematic cross-sectional view of FIG. 17 taken along line A-A according to an embodiment of the present application; and

FIG. 19 is a schematic flowchart of a method for preparing a display panel according to an embodiment of the present application.

List of reference signs: 1. Array substrate; 2. Pixel defining layer; 21. Pixel opening; 3. Isolation structure; 31. Conductive portion; 32. Isolation portion; 321. First isolation portion; 322. Second isolation portion; 33. Blocking portion; 4. Isolation opening; 5. Recess; 6. Light-emitting functional layer; 61. Hole injection layer; 62. Hole transport layer; 63. Light-emitting layer; 64. Electron transport layer; 65. Electron injection layer; 7. First electrode; 8. Second electrode; 9. Light-emitting unit; 10. Charge generation layer; 11. First encapsulation layer; 111. Encapsulation unit; 12. Second encapsulation layer; 13. Third encapsulation layer; 14. Filter layer; 141. Filtering portion; 142. Shielding portion; 15. Touch electrode; 16. Bridging trace; 17. Touch layer; 171. Touch trace; 18. Light-transmitting opening.

### DETAILED DESCRIPTION OF THE EMBODIMENTS

In order to make the objectives, technical solutions and advantages of embodiments of the present application clearer, the technical solutions in the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

Thus, the following detailed description of the embodiments of the present application provided in the accompanying drawings is not intended to limit the scope of the present application as claimed, but is merely representative of the selected embodiments of the present application. Based on the embodiments of the present application, all other embodiments obtained by those of ordinary skill in the art without involving any inventive effort shall fall within the scope of protection of the present application.

It should be noted that like items are denoted by like numerals and letters in the following drawings. Therefore, once a specific item is defined in one of the drawings, the item needs not to be further defined and explained in subsequent drawings.

In the description of the present application, it should be noted that orientations or position relationships indicated by terms such as “center,” “upper,” “lower”, “vertical”, “horizontal”, “inner”, and “outer” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application. In addition, the terms such as “first”, “second” and “third” are merely intended to distinguish the description, and are not to be construed as indicating or implying relative importance.

It should be noted that different features in the embodiments of the present application may be combined with each other without conflicts.

Increasing the density (i.e. pixel density) of light-emitting units in a display panel is an important way to improve the display effect. However, display panels currently made by using the fine metal mask (FMM) technology are unable to further increase the density of light-emitting units due to technical limitations. The inventors have found, after long-term research, that in order to solve the technical problem that the density of light-emitting units cannot be further increased, isolation structures are provided in some display panels, and during the full-layer evaporation of light-emitting functional layers and cathodes, the light-emitting functional layers and the cathodes can be disconnected at the isolation structures, and light-emitting units of different colors can be formed in different isolation openings by means of multiple evaporation and multiple etching processes (i.e., patterning the light-emitting units).

Reference is made to the relevant technical solutions of the isolation structure and the encapsulation layer described in patents PCT/CN2023/134518, 202310759370.2, 202310740412.8, 202310707209.0, 202311499823.9, 202310692671.8, 202311091555.7 and 202311346196.5, the contents of which are incorporated herein by reference.

In the above display panel, it has been found by the inventors after long-term research that an inorganic encapsulation layer for encapsulating the light-emitting units at the contact with the isolation structure is thin, and the inorganic encapsulation layer at this location is prone to rupture, which makes the encapsulation of the inorganic encapsulation layer on the light-emitting units easily fail, affecting the display effect of the display panel.

In order to solve the technical problems mentioned above, the inventors have innovatively designed the following technical solutions. The specific implementations of the present application will be described in detail below with reference to the accompanying drawings. It should be noted that the defects of the above solutions in the prior art are the results obtained by the inventors after practice and careful research.

Therefore, the process of discovering the above technical problem and the solutions proposed in the following embodiments for the above problem should be regarded as the contributions made by the inventors to the present application during invention and creation, and should not be construed as the technical content that is well known to those skilled in the art.

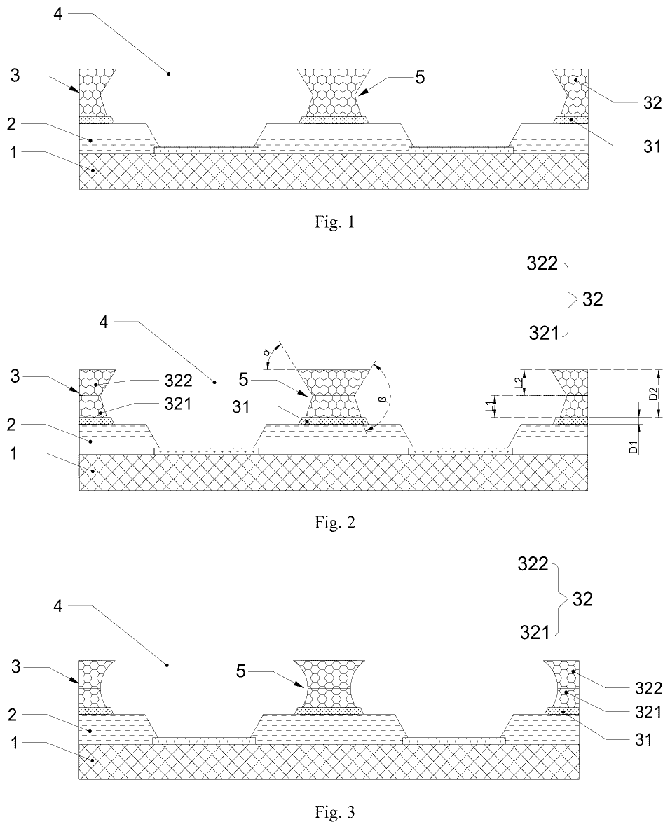

Referring to FIG. 1, this embodiment provides a display panel. The display panel includes an array substrate 1, and an isolation structure 3.

The array substrate 1 may include a substrate and a plurality of drive units located on a side of the substrate, and each drive unit may include one or more semiconductor switching devices. The semiconductor switching device may be formed collectively by a plurality of film layers in the array substrate 1. For example, the semiconductor switching device may be a thin film transistor formed collectively by a plurality of film layers.

The isolation structure 3 is located on a side of the array substrate 1, the isolation structure 3 encloses a plurality of isolation openings 4, and the isolation structure 3 includes a conductive portion 31 and an isolation portion 32 which are sequentially stacked in a direction away from the array substrate 1. The isolation portion 32 includes a recess 5 that is recessed in a direction away from the isolation opening 4.

Because the recess 5 that is recessed in the direction away from the isolation opening 4 is provided in the isolation portion 32, during the process of forming an inorganic encapsulation layer, a reactive gas enters the isolation opening 4 more easily and circulates in the isolation opening 4 more easily. In this way, the reactive gas is easier to continuously form a film on a side wall of the isolation portion 32 facing the isolation opening 4, eventually forming an inorganic encapsulation layer having a film with a larger and more uniform thickness, thereby making the inorganic encapsulation layer less prone to rupture and not easily fail, which in turn improves the display effect of the display panel.

On the basis of the above design, in this embodiment, the recess 5 that is recessed in the direction away from the isolation opening 4 is provided in the isolation portion 32 such that it is possible to make the inorganic encapsulation layer at the contact with the isolation structure 3 more continuous and thicker, thereby improving the encapsulation effect of the inorganic encapsulation layer, which can in turn improve the display effect of the display panel.

In some possible implementations, referring to FIG. 2, the isolation portion 32 includes a first isolation portion 321 and a second isolation portion 322 sequentially stacked in a direction away from the array substrate 1. The recess 5 is formed at the contact between sides of the first isolation portion 321 and the second isolation portion 322 facing the isolation opening 4. An orthographic projection of a side of the first isolation portion 321 away from the array substrate 1 on the array substrate 1 is located within an orthographic projection of a side of the first isolation portion 321 close to the array substrate 1 on the array substrate 1. An orthographic projection of a side of the second isolation portion 322 close to the array substrate 1 on the array substrate 1 is located within an orthographic projection of a side of the second isolation portion 322 away from the array substrate 1 on the array substrate 1.

A cross section of the first isolation portion 321 in a direction perpendicular to the array substrate 1 is shaped to be narrower at the top and wider at the bottom, and a cross section of the second isolation portion 322 in the direction perpendicular to the array substrate 1 is shaped to be wider at the top and narrower at the bottom. Therefore, the recess 5 that is recessed in the direction away from the isolation opening 4 is formed at the contact between the first isolation portion 321 and the second isolation portion 322, such that reactive gas for the inorganic encapsulation layer circulates in the recess 5 more easily, thereby forming the inorganic encapsulation layer on the isolation structure 3 with a better encapsulation effect.

Preferably, referring again to FIG. 2, the orthographic projection of the side of the second isolation portion 322 close to the array substrate 1 on the array substrate 1 coincides with the orthographic projection of the side of the first isolation portion 321 away from the array substrate 1 on the array substrate 1, an orthographic projection of the first isolation portion 321 on the array substrate 1 is located within an orthographic projection of the second isolation portion 322 on the array substrate 1, the orthographic projection of the first isolation portion 321 on the array substrate 1 is located within an orthographic projection of the conductive portion 31 on the array substrate 1, and the orthographic projection of the second isolation portion 322 on the array substrate 1 is located within the orthographic projection of the conductive portion 31 on the array substrate 1.

The side of the first isolation portion 321 away from the array substrate 1 and the side of the second isolation portion 322 close to the array substrate 1 coincide completely. In this way, the recess 5 formed by the first isolation portion 321 and the second isolation portion 322 is smoother, and the reactive gas for the inorganic encapsulation layer circulates better in the recess 5.

The conductive portion 31 may project relative to the second isolation portion 322, such that when the second isolation portion 322 separates the second electrodes 8 of the display panel, the second electrodes 8 more easily overlaps with the conductive portion 31.

Preferably, materials of the first isolation portion 321 and the second isolation portion 322 are the same, the first isolation portion 321 is formed integrally with the second isolation portion 322, each of the materials of the first isolation portion 321 and the second isolation portion 322 includes an organic material, and a material of the conductive portion 31 includes indium tin oxide. In this way, the isolation portion 32 can be prepared more easily, and the preparation cost of the isolation portion 32 can be reduced.

In some possible implementations, referring again to FIG. 2, in a cross section in a direction perpendicular to the array substrate 1, a dimension of the second isolation portion 322 gradually increases in a direction away from the array substrate 1, and a dimension of the first isolation portion 321 is gradually reduced in the direction away from the array substrate 1.

In the cross section in the direction perpendicular to the array substrate 1, the side of the second isolation portion 322 facing the isolation opening 4 includes a straight section and/or a curved section, and the side of the first isolation portion 321 facing the isolation opening 4 includes a straight section and/or a curved section.

In some embodiments, referring again to FIG. 2, in the cross section in the direction perpendicular to the array substrate 1, the sides of the first isolation portion 321 and the second isolation portion 322 facing the isolation opening 4 each include a straight section, that is, the shape of the cross section of the first isolation portion 321 is trapezoidal, and the shape of the cross section of the second isolation portion 322 is inverted trapezoidal.

In some other embodiments, referring to FIG. 3, in the cross section in the direction perpendicular to the array substrate 1, the sides of the first isolation portion 321 and the second isolation portion 322 facing the isolation opening 4 each include a curved section, that is, the sides of the first isolation portion 321 and the second isolation portion 322 facing the isolation opening 4 are curved.

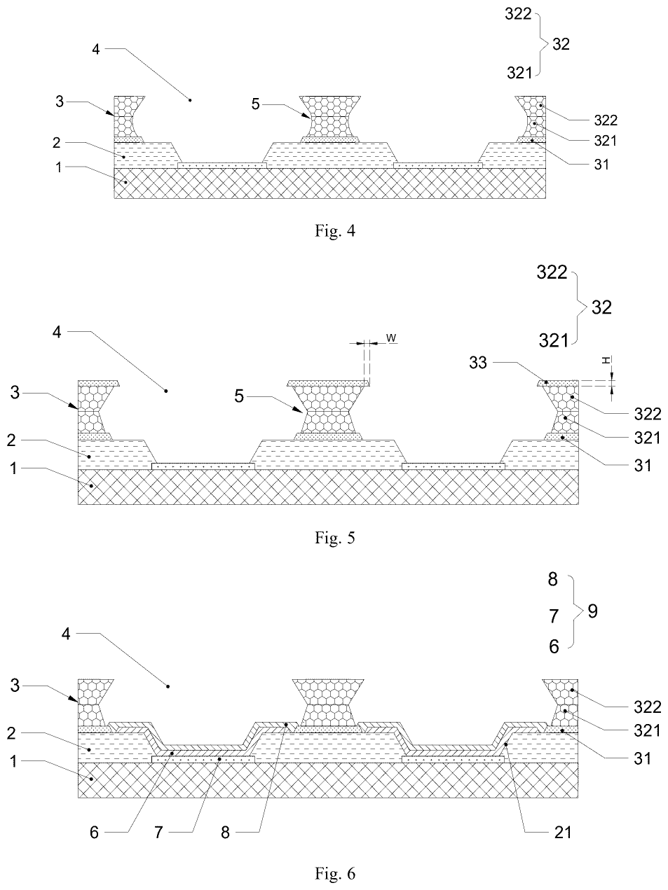

In further embodiments, referring to FIG. 4, the sides of the first isolation portion 321 and the second isolation portion 322 facing the isolation opening 4 each include a curved section and a straight section.

In the above embodiments, during the process of forming a first encapsulation layer 11, it is more advantageous for the reactive gas to circulate within the isolation opening 4, and it is easier for the reactive gas to continuously form a film on the side wall of the isolation portion 32 facing the isolation opening 4, eventually forming inorganic encapsulation layers having a larger and more uniform film layer thickness on the side wall of the isolation structure 3 facing the isolation opening 4, and in particular on an edge of the isolation opening 4.

In some possible implementations, referring again to FIG. 2, an included angle ß between the side of the first isolation portion 321 facing the isolation opening 4 and the side of the second isolation portion 322 facing the isolation opening 4 is an obtuse angle.

Preferably, the included angle ß between the side of the first isolation portion 321 facing the isolation opening 4 and the side of the second isolation portion 322 facing the isolation opening 4 ranges from 105° to 135°, for example, the included angle ß can be 105°, 110°, 120°, 130°, 135°, etc. By properly setting the included angle, a thickness of the inorganic encapsulation layer in contact with the isolation structure 3 and the uniformity of a film layer can be further improved, such that the encapsulation effect of the inorganic encapsulation layer can be further improved.

Preferably, an included angle α between the side of the second isolation portion 322 facing the isolation opening 4 and the side of the second isolation portion 322 away from the array substrate 1 ranges from 15°to 45°, for example, the included angle α can be 15°, 20°, 30°, 35°, 40°, 45°, etc. By properly setting the included angle α, it may be more advantageous to form a thicker and more uniform inorganic encapsulation layer on the side of the isolation portion 32 facing the isolation opening 4.

In some possible implementations, referring again to FIG. 2, in the direction perpendicular to the array substrate 1, a ratio of a thickness D1 of the conductive portion 31 to a thickness D2 of the isolation portion 32 ranges from 1:10 to 1:2. For example, the ratio of the thickness D1 to the thickness D2 can be 1:10, 1:9, 1:7, 1:5, 1:3, 1: 2, etc. The overall structure of the isolation structure 3 can be properly configured by properly setting ratio of the thickness D1 to the thickness D2, such that a thicker and more uniform inorganic encapsulation layer can be formed on the side of the isolation portion 32 facing the isolation opening 4.

Preferably, referring again to FIG. 2, in the direction perpendicular to the array substrate 1, the thickness D1 of the conductive portion 31 ranges from 1,000 Å to 3,000 Å. For example, the thickness D1 can be 1,000 Å, 1,500 Å, 2,000 Å, 2,500 Å, 3,000 Å, etc.

In the direction perpendicular to the array substrate 1, the isolation portion 32 has the thickness D2 of 6,000 Å-10,000 Å. For example, the thickness D2 can be 6,000 Å, 6,500 Å, 7,000 Å, 7,500 Å, 8,000 Å, 9,000 Å, 9,500 Å, 10,000 Å, etc.

In this embodiment, the thickness D1 of the conductive portion 31 is much less than the thickness D2 of the isolation portion 32. By properly setting the thickness D1 and the thickness D2, it may be more advantageous to form a thicker and more uniform inorganic encapsulation layer on the side of the isolation portion 32 facing the isolation opening 4, which can also improve the overall stability of the isolation structure 3.

Preferably, referring again to FIG. 2, in the direction perpendicular to the array substrate 1, a ratio of a thickness L1 of the first isolation portion 321 to a thickness L2 of the second isolation portion 322 ranges from 1:2 to 2:1. For example, the ratio of the thickness L1 to the thickness L2 can be 1:2, 2:3, 1:1, 6:5, 2:1, etc. The overall structure of the isolation portion 32 can be properly configured by properly setting ratio of the thickness L1 to the thickness L2, such that a thicker and more uniform inorganic encapsulation layer can be formed on the side of the isolation portion 32 facing the isolation opening 4.

Preferably, in the direction perpendicular to the array substrate 1, the thickness L1 of the first isolation portion 321 ranges from 3,000 Å to 6,000 Å. For example, the thickness L1 can be 3,000 Å, 3,500 Å, 4,000 Å, 4,500 Å, 5,000 Å, 5,500 Å, 6,000 Å, etc.

In the direction perpendicular to the array substrate 1, the thickness L2 of the second isolation portion 322 ranges from 3,000 Å to 6,000 Å. For example, the thickness L2 can be 3,000 Å, 3,500 Å, 4,000 Å, 4,500 Å, 5,000 Å, 5,500 Å, 6,000 Å, etc.

In this embodiment, the thickness L1 of the first isolation portion 321 is substantially equal to the thickness L2 of the second isolation portion 322. By properly setting the thickness L1 and the thickness L2, it may be more advantageous to form a thicker and more uniform inorganic encapsulation layer on the side of the isolation portion 32 facing the isolation opening 4, which can also improve the overall stability of the isolation structure 3.

Preferably, in the direction perpendicular to the array substrate 1, the thickness L1 of the first isolation portion 321 is equal to the thickness L2 of the second isolation portion 322. In this way, it is more advantageous to form a thicker and more uniform inorganic encapsulation layer on the side of the isolation portion 32 facing the isolation opening 4.

In some possible implementations, referring to FIG. 5, the isolation structure 3 further includes a blocking portion 33 on the side of the isolation portion 32 away from the array substrate 1. An orthographic projection of the blocking portion 33 on the array substrate 1 at least partially coincides with the orthographic projection of the isolation portion 32 on the array substrate 1.

It has been found by the inventors after long term research that when the organic material layer and/or inorganic material layer are patterned by wet etching to form the isolation portion 32, an etching solution can easily corrode the material layer, resulting in the topography of the isolation portion 32 being less likely to meet the requirements. In order to solve this problem, in this embodiment, the provision of the blocking portion 33 on the side of the isolation portion 32 away from the array substrate 1 enables better protection of the material of the isolation portion 32, such that the isolation portion 32 which better satisfies the requirements can be formed, which can in turn improve the quality of the display panel.

Preferably, referring again to FIG. 5, the orthographic projection of the side of the isolation portion 32 away from the array substrate 1 on the array substrate 1 is located within an orthographic projection of the blocking portion 33 on the array substrate 1, a minimum spacing W between an edge of the orthographic projection of the isolation portion 32 on the array substrate 1 and an edge of the orthographic projection of the blocking portion 33 on the array substrate 1 is 0-0.5 μm. For example, the spacing W can be 0, 0.1 μm, 0.2 μm, 0.3 μm, 0.4 μm, 0.5 μm, etc. Properly setting the spacing W allows better protection of the isolation portion 32 and easier overlap of the cathode with the conductive portion 31 in the subsequent formation of the cathode.

Preferably, referring again to FIG. 5, in the direction perpendicular to the array substrate 1, a thickness H of the blocking portion 33 is greater than or equal to 0.15 μm. For example, the thickness H can be 0.15 μm, 0.2 μm, 0.3 μm, 0.5 μm, etc. Properly setting the thickness H enables more effective protection of the isolation portion 32 without excessively increasing a thickness of the display panel.

Preferably, the blocking portion 33 includes a corrosion-resistant material, and particularly at least one of metallic titanium, metallic copper, metallic molybdenum, and indium tin oxide. The blocking portion 33 formed of a corrosion-resistant material provides more effective protection for the isolation portion 32.

In some possible implementations, referring to FIG. 6, the display panel further includes a plurality of light-emitting units 9 at least partially located within the plurality of isolation openings 4. Each of the plurality of light-emitting units 9 includes a first electrode 7, a light-emitting functional layer 6 and a second electrode 8 which are stacked in sequence in a direction away from the array substrate 1. The display panel further includes a pixel defining layer 2 located on a side of a film layer in which the first electrodes 7 are located away from the array substrate 1, and the isolation structure 3 is located on a side of the pixel defining layer 2 away from the array substrate 1. The pixel defining layer 2 includes pixel openings 21 each exposing at least part of the first electrode 7. An orthographic projection of the pixel opening 21 on the array substrate 1 is located within the orthographic projection of the isolation opening 4 on the array substrate 1.

The isolation structure 3 is provided such that the plurality of light-emitting units 9 of different colors can be formed in the display panel in the different isolation openings 4 without a fine metal mask. Particularly, because the second isolation portion 322 is inverted trapezoidal, when the light-emitting functional layer 6 is formed, the light-emitting functional layer 6 may be separated by the isolation structure 3 to form a plurality of light-emitting portions spaced apart; and when a second electrode layer is formed, the second electrode layer may be separated by the isolation structure 3 to form a plurality of second electrodes 8 spaced apart. The isolation structure 3 includes a conductive material, the second electrodes 8 are electrically connected to the isolation structure 3, and one first electrode 7, one light-emitting portion and one second electrode 8 form one light-emitting unit 9. The first electrode 7 may be an anode, and the second electrode 8 may be a cathode.

In this way, the different light-emitting units 9 can be independent of each other, such that cross-talk between adjacent light-emitting units 9 can be ameliorated and the display effect of the display panel can be improved. In addition, due to the presence of the isolation structure 3, each of the light-emitting functional layer 6 and the second electrode 8 of the light-emitting unit 9 of each color of the display panel can be prepared over its entire surface first and then patterned, thus eliminating the need for a fine metal mask and reducing the preparation cost of the display panel.

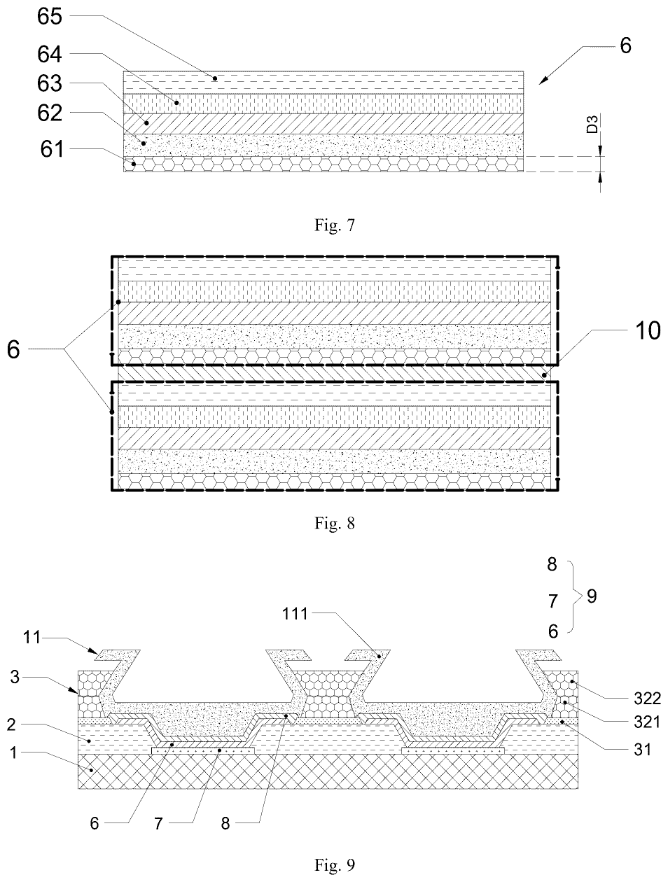

Preferably, referring to FIG. 7, the light-emitting functional layer 6 includes a hole injection layer 61 on a side of the first electrode 7, and a hole transport layer 62, a light-emitting layer 63, an electron transport layer 64 and an electron injection layer 65 which are stacked in sequence on the hole injection layer 61 in a direction away from the first electrode 7.

Referring to FIG. 8, the number of light-emitting functional layers 6 is plural, and the light-emitting unit 9 further includes a charge generation layer 10 between any two adjacent light-emitting functional layers 6. In this way, the light-emitting unit 9 is a stack structure, such that the luminous effect of the light-emitting unit 9 can be improved.

Preferably, referring again to FIGS. 2 and 7, in the direction perpendicular to the array substrate 1, the thickness D1 of the conductive portion 31 is less than a thickness D3 of the hole injection layer 61. In this way, a lateral current leakage from the light-emitting unit 9 can be reduced, such that the luminous effect of the light-emitting unit 9 can be improved.

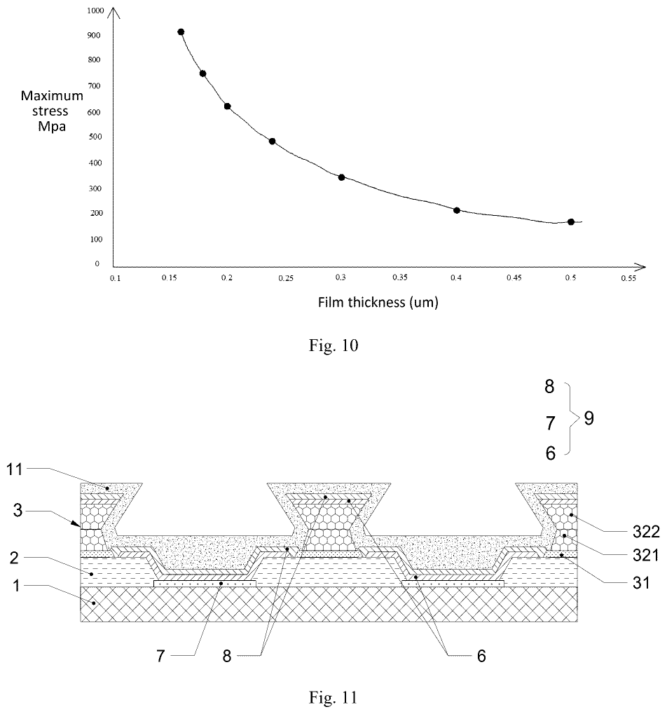

Preferably, referring to FIG. 9, the display panel further includes a first encapsulation layer 11 that are sequentially stacked on sides of the light-emitting units 9 away from the array substrate 1.

The first encapsulation layer 11 in this embodiment are the inorganic encapsulation layers in the above embodiments. The thicker the film layer of the first encapsulation layer 11 is, the smaller the stress to be subjected is, and the stronger the stress resistance is. As shown in FIG. 10, the abscissa in FIG. 10 represents the thickness of the film layer, in μm, and the ordinate shows a maximum stress on the film layer, in Mpa. It can be seen from FIG. 10 that the maximum stress experienced by the film layer is attenuated rapidly with increasing film layer thickness. For example, when the film layer thickness is changed from 0.15 microns to 0.45 microns, the maximum stress experienced by the film layer decreases from around 1,000 Mpa to around 180 Mpa, and the stress on the film layer is reduced to about ⅙ of the original stress.

As can be seen from FIG. 9, during the formation of the first encapsulation layer 11, a material of the first encapsulation layer 11 circulates more easily in the plurality of isolation openings 4, and thus the thickness of the first encapsulation layer 11 is larger at the contact with the isolation structure 3, resulting in better uniformity. Therefore, the first encapsulation layer 11 in contact with the isolation structure 3 are not prone to rupture, and the issue of encapsulation failure is not likely to occur, such that the encapsulation effect on the light-emitting units 9 can be improved.

Preferably, each of the first encapsulation layer 11 extends into the recess 5. In this way, the adhesion between the first encapsulation layer 11 and the side of the isolation structure 3 facing the isolation opening 4 can be further increased, such that the stability of the first encapsulation layer 11 can be further improved.

In some embodiments, referring again to FIG. 9, the first encapsulation layer 11 includes a plurality of encapsulation units 111 spaced apart. At least part of the encapsulation units 111 extend from a side of the isolation structure 3 facing the plurality of isolation openings 4 to a side of the isolation structure 3 away from the array substrate 1, the encapsulation units 111 are spaced apart on the side of the isolation structure 3 away from the array substrate 1, with gaps between the encapsulation units 111 on the sides of the isolation structure 3 away from the array substrate 1 and the side of the isolation structure 3 away from the array substrate 1.

In this embodiment, regardless of whether or not the emitting colors of the light-emitting units 9 are the same, each light-emitting unit 9 corresponds to one encapsulation unit 111. Particularly, during the patterning of the light-emitting units 9, the first encapsulation layer 11 is disconnected at the isolation structure 3 to form the encapsulation units 111. The encapsulation units 111 can encapsulate corresponding light-emitting units 9 completely and independently, such that the display characteristics of the display panel can be improved.

In other embodiments, referring to FIG. 11, a plurality of encapsulation units 111 for at least part of the plurality of light-emitting units 9 are disposed continuously on the side of the isolation structure 3 away from the array substrate 1. Particularly, a plurality of encapsulation units 111 for a plurality of light-emitting units 9 of the same emitting color are disposed continuously on the side of the isolation structure 3 away from the array substrate 1.

Referring again to FIG. 9, at least two encapsulation units 111 for at least two light-emitting units 9 of different emitting colors are spaced apart on the side of the isolation structure 3 away from the array substrate 1.

In this embodiment, the emitting colors of two light-emitting units 9 in FIG. 9 are different. For example, the emitting color of one of the light-emitting units 9 in FIG. 9 is red, and the emitting color of the other of the light-emitting units 9 is green. Two encapsulation units 111 for the two light-emitting units 9 are spaced apart on the side of the isolation structure 3 away from the array substrate 1.

Two light-emitting units 9 in FIG. 11 have the same emitting color. For example, the emitting colors of the two light-emitting units 9 in FIG. 11 are red, and a plurality of encapsulation units 111 for the two light-emitting units 9 are disposed continuously on the side of the isolation structure 3 away from the array substrate 1.

In this way, the first encapsulation layer 11 can be configured more flexibly according to actual needs, to meet different needs.

Preferably, referring again to FIG. 11, the light-emitting functional layer 6 and the second electrode 8 are also located between the first encapsulation layer 11 for the light-emitting units 9 of the same emitting color and the side of the isolation structure 3 away from the array substrate 1. The light-emitting functional layer 6 located between the first encapsulation layer 11 and the side of the isolation structure 3 away from the array substrate 1 is disposed at a distance from the light-emitting functional layer 6 located within the isolation opening 4. The second electrode 8 located between the first encapsulation layer 11 and the side of the isolation structure 3 away from the array substrate 1 is disposed at a distance from the second electrode 8 located within the isolation opening 4.

In this way, the second electrode 8 and the light-emitting functional layer 6 located between the first encapsulation layer 11 and the side of the isolation structure 3 away from the array substrate 1 may fill the gap between the first encapsulation layer 11 and the side of the isolation structure 3 away from the array substrate 1, such that the connection between the first encapsulation layer 11 and the isolation structure 3 can be more stable, which in turn can make the first encapsulation layer 11 less prone to failure.

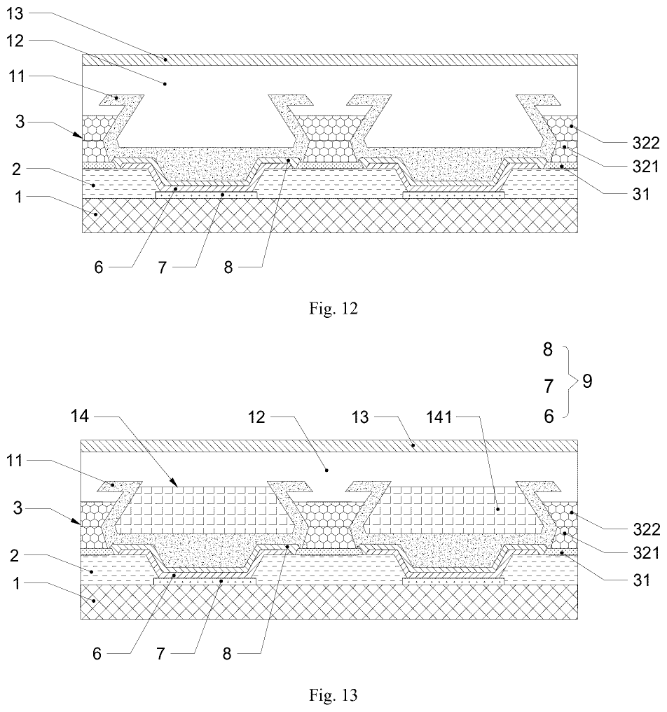

Preferably, referring to FIG. 12, the display panel further includes a second encapsulation layer 12 on the side of the first encapsulation layer 11 away from the array substrate 1 and a third encapsulation layer 13 on a side of the second encapsulation layer 12 away from the array substrate 1. The first encapsulation layer 11 and the third encapsulation layer 13 each include an inorganic material, and the second encapsulation layer 12 includes an organic material.

For example, the first encapsulation layer 11 and the third encapsulation layer 13 may be formed by chemical vapor deposition (CVD), and the second encapsulation layer 12 may be formed by ink-jet printing (IJP). The second encapsulation layer 12 and the third encapsulation layer 13 can offer a better encapsulation effect on the light-emitting units 9, such that the encapsulation quality of the display panel can be further improved.

In some possible implementations, referring to FIG. 13, the display panel further includes a filter layer 14 on the side of the first encapsulation layer 11 away from the array substrate 1. The filter layer 14 includes a filtering portion 141. An orthographic projection of the filtering portion 141 on the array substrate 1 covers at least part of the orthographic projection of the light-emitting unit 9 on the array substrate 1, and the transmitting color of the filtering portion 141 is the same as the emitting color of a corresponding light-emitting unit 9.

A plurality of filtering portions 141 are spaced apart such that when the emitting colors of the light-emitting units 9 are red, the transmitting colors of the plurality of filtering portions 141 on the sides of the light-emitting units 9 away from the array substrate 1 are red, and when the emitting colors of the light-emitting units 9 are green, the transmitting colors of the plurality of filtering portions 141 on the sides of the light-emitting units 9 away from the array substrate 1 are green, and when the emitting colors of the light-emitting units 9 are blue, the transmitting colors of the plurality of filtering portions 141 on the sides of the light-emitting units 9 away from the array substrate 1 are blue. In this way, the color of the light emitted by the light-emitting units 9 can be made purer by the plurality of filtering portions 141, such that the display effect of the display panel can be improved.

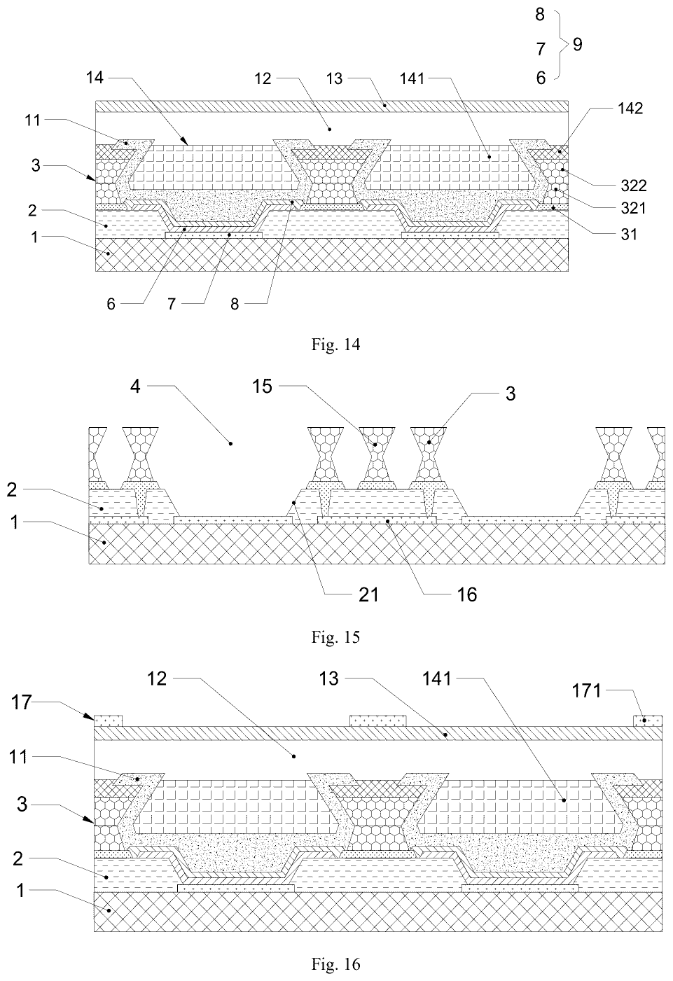

Preferably, referring to FIG. 14, the filter layer 14 further includes a shielding portion 142. The shielding portion 142 is disposed at a distance from the plurality of filtering portions 141.

In some embodiments, referring again to FIG. 13, the isolation structure 3 acts as the shielding portion. In this embodiment, the entire isolation structure 3 may act as the shielding portion, or part of the isolation structure 3 may act as the shielding portion. For example, the second isolation portion 322 acts as the shielding portion. The cross-talk of light between the light-emitting units 9 of different colors can be reduced by the shielding portion in this embodiment, such that the display effect of the display panel can be further improved.

In some other embodiments, referring again to FIG. 14, the shielding portion 142 is located on the side of the isolation structure 3 away from the array substrate 1, and an orthographic projection of the shielding portion 142 on the array substrate 1 is located within the orthographic projection of the isolation structure 3 on the array substrate 1.

In this embodiment, the shielding portion 142 may be disposed in the same layer as the plurality of filtering portions 141. A material of the shielding portion 142 may be a black adhesive, and the cross-talk of light between the light-emitting units 9 of different colors may be reduced by the shielding portion 142 in this embodiment. The orthographic projection of the shielding portion 142 on the array substrate 1 is arranged within the orthographic projection of the isolation structure 3 on the array substrate 1 such that the blocking of the light emitted by the light-emitting unit 9 in a large-view-angle direction by the shielding portion 142 can be reduced, thereby further improving the display effect of the display panel.

In some possible implementations, the display panel also has a touch function.

In some embodiment, referring to FIG. 15, the display panel further includes a plurality of touch electrodes 15 disposed in the same layer as the isolation structure 3. The plurality of touch electrodes 15 are isolated from the isolation structure 3.

In this embodiment, the plurality of touch electrodes 15 are formed while the isolation structure 3 is formed, and the plurality of touch electrodes 15 may be configured as self-contained touch electrodes 15. It is also possible for the isolation structure 3 to act as touch electrodes, that is, one of the plurality of touch electrodes 15 and the isolation structure 3 are configured as touch receiving electrodes and the other are configured as touch transmitting electrodes.

The isolation structure 3 located on two sides of the plurality of touch electrodes 15 can be electrically connected by a bridging trace 16. The bridging trace 16 can be located in a first electrode 7 layer, that is, the bridging trace 16 is formed while the first electrode 7 is formed. In this way, it is unnecessary to specifically provide a process for forming the bridging trace 16, which can reduce the preparation cost of the display panel.

In some other embodiments, referring to FIG. 16, the display panel further includes touch layers 17 on the side of the isolation structure 3 away from the array substrate 1. The touch layers 17 each include touch traces 171. In this embodiment, the touch layers 17 are disposed on the side of the third encapsulation layer 13 away from the array substrate 1, the touch function of the display panel can be realized by the touch traces 171.

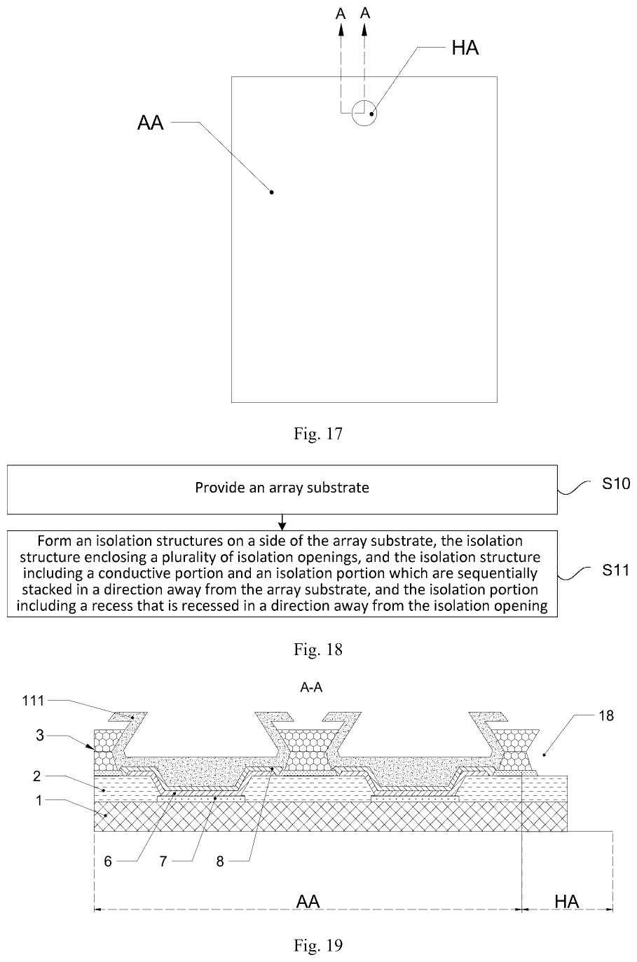

In some possible implementations, referring to FIGS. 17-18, the display panel includes a hole area HA and an active area AA at least partially surrounding the hole area HA. The isolation structure 3 also encloses a plurality of light-transmitting openings 18. The plurality of light-transmitting openings 18 are located in the hole area HA, and an orthographic projection of the plurality of light-transmitting openings 18 on the array substrate 1 are located outside the orthographic projections of the isolation openings 4 on the array substrate 1.

A photosensitive device can be provided under a screen in the hole area HA, for example, a camera can be provided, and light from the outside can reach the position of the camera through the plurality of light-transmitting openings 18 to achieve a camera function of the display panel.

In some possible implementations, referring to FIGS. 18-19, the present application further provides a method for preparing a display panel, the method including:
step S10: providing an array substrate 1; and
step S11: forming an isolation structure 3 on one side of the array substrate 1, the isolation structure 3 enclosing a plurality of isolation openings 4, and the isolation structure 3 including a conductive portion 31 and an isolation portion 32 which are sequentially stacked in a direction away from the array substrate 1, and the isolation portion 32 including a recess 5 that is recessed in a direction away from the isolation opening 4.

In the display panel formed according to the above method, the recess 5 that is recessed in the direction away from the isolation opening 4 is provided in the isolation portion 32, during the process of forming an inorganic encapsulation layer, a reactive gas enters the isolation opening 4 more easily and circulates in the isolation opening 4 more easily. In this way, the reactive gas is easier to continuously form a film on a side wall of the isolation portion 32 facing the isolation opening 4, eventually forming an inorganic encapsulation layer having a film with a larger and more uniform thickness, thereby making the inorganic encapsulation layer less prone to rupture and not easily fail, which in turn improves the display effect of the display panel.

In some possible implementations, the present application further provides an electronic device, including a display panel in the present application, or including a display panel prepared by means of a method for preparing the display panel in the present application. The electronic device may include a device having image processing capability, for example, a server, a personal computer, a notebook computer, etc. Since the electronic device includes the display panel according to the present application, the electronic device has better encapsulation and display effects.

The technical features of the above embodiments may be combined arbitrarily. For the purpose of brevity of description, all the possible combinations of the technical features in the above embodiments are not described. However, as long as there is no contradiction between the combinations of these technical features, they shall all fall within the scope of the specification.

The above embodiments merely represent several implementations of the present application, giving specifics and details thereof, but should not be understood as limiting the scope of the present application thereby. It should be noted that various variations and improvements may also be made by those of ordinary skill in the art without departing from the spirit of the present application and shall fall within the scope of protection of the present application. Therefore, the scope of protection of the present application shall be in accordance with the appended claims.

1. A display panel, comprising:
an array substrate;
an isolation structure located on a side of the array substrate, the isolation structure enclosing a plurality of isolation openings, and the isolation structure comprising a conductive portion and an isolation portion which are sequentially stacked in a direction away from the array substrate, and the isolation portion comprising a recess that is recessed in a direction away from the isolation opening.

2. The display panel according to claim 1, wherein the isolation portion comprises a first isolation portion and a second isolation portion sequentially stacked in a direction away from the array substrate, the recess is formed at a contact between sides of the first isolation portion and the second isolation portion facing an isolation opening of the plurality of isolation openings;
an orthographic projection of a side of the first isolation portion away from the array substrate on the array substrate is located within an orthographic projection of a side of the first isolation portion close to the array substrate on the array substrate; and
an orthographic projection of a side of the second isolation portion close to the array substrate on the array substrate is located within an orthographic projection of a side of the second isolation portion away from the array substrate on the array substrate.

3. The display panel according to claim 2, wherein an orthographic projection of a side of the second isolation portion close to the array substrate on the array substrate coincides with anthe orthographic projection of the side of the first isolation portion away from the array substrate on the array substrate;
an orthographic projection of the first isolation portion on the array substrate is located within an orthographic projection of the second isolation portion on the array substrate;
the orthographic projection of the first isolation portion on the array substrate is located within an orthographic projection of the conductive portion on the array substrate; and
the orthographic projection of the second isolation portion on the array substrate is located within the orthographic projection of the conductive portion on the array substrate.

4. The display panel according to claim 2, wherein materials of the first isolation portion and the second isolation portion are the same;
the first isolation portion is formed integrally with the second isolation portion; and
each of the materials of the first isolation portion and the second isolation portion comprises an organic material.

5. The display panel according to claim 2, wherein in a cross section in a direction perpendicular to the array substrate, a dimension of the second isolation portion gradually increases in the direction away from the array substrate; and
in the cross section in the direction perpendicular to the array substrate, a side of the second isolation portion facing the isolation opening comprises at least one of a straight section and a curved section.

6. The display panel according to claim 2, wherein in a cross section in a direction perpendicular to the array substrate, a dimension of the first isolation portion is gradually reduced in the direction away from the array substrate; and
in the cross section in the direction perpendicular to the array substrate, a side of the first isolation portion facing the isolation opening comprises at least one of a straight section and a curved section.

7. The display panel according to claim 2, wherein an included angle between the side of the first isolation portion facing the isolation opening and the side of the second isolation portion facing the isolation opening is an obtuse angle; and
an included angle between the side of the second isolation portion facing the isolation opening and the side of the second isolation portion away from the array substrate ranges from 15° to 45°.

8. The display panel according to claim 2, wherein in the direction perpendicular to the array substrate, a ratio of a thickness of the conductive portion to a thickness of the isolation portion ranges from 1:10 to 1:2;
in the direction perpendicular to the array substrate, the thickness of the conductive portion ranges from 1000 Å to 3000 Å;
in the direction perpendicular to the array substrate, the thickness of the isolation portion ranges from 6.000 Å to 10,000 Å;
in the direction perpendicular to the array substrate, a ratio of a thickness of the first isolation portion to a thickness of the second isolation portion ranges from 1:2 to 2:1;
in the direction perpendicular to the array substrate, the thickness of the first isolation portion ranges from 3,000 Å to 6,000 Å;
in the direction perpendicular to the array substrate, the thickness of the second isolation portion ranges from 3.000 Å to 6.000 Å; and
in the direction perpendicular to the array substrate, the thickness of the first isolation portion is equal to the thickness of the second isolation portion.

9. The display panel according to claim 1, wherein the isolation structure further comprises a blocking portion on the side of the isolation portion away from the array substrate, and an orthographic projection of the blocking portion on the array substrate at least partially coincides with an orthographic projection of the isolation portion on the array substrate.

10. The display panel according to claim 9, wherein a minimum spacing between an edge of the orthographic projection of the isolation portion on the array substrate and an edge of the orthographic projection of the blocking portion on the array substrate ranges from 0 to 0.5 μm;
a direction perpendicular to the array substrate, a thickness of the blocking portion is greater than or equal to 0.15 μm;
a material of the blocking portion comprises at least one of metallic titanium, metallic copper, metallic molybdenum, and indium tin oxide; and
a material of the conductive portion comprises indium tin oxide.

11. The display panel according to claim 1, further comprising a plurality of light-emitting units at least partially located within the plurality of isolation openings, wherein each of the plurality of light-emitting units comprises a first electrode, a light-emitting functional layer; and a second electrode which are stacked in sequence in a direction away from the array substrate;
the light-emitting functional layer comprises a hole injection layer located on a side of the first electrode;
the light-emitting functional layer further comprises a hole transport layer, a light-emitting layer, an electron transport layer, and an electron injection layer which are stacked in sequence on the hole injection layer in a direction away from the first electrode; and
a number of the light-emitting functional layers is plural, the plurality of light-emitting functional layers are stacked, and the light-emitting unit further comprises a charge generation layer between any adjacent two of the light-emitting functional layers.

12. The display panel according to claim 11, wherein in a direction perpendicular to the array substrate, a thickness of the conductive portion is less than a thickness of the hole injection layer;
the display panel further comprises a pixel defining layer located on a side of a film layer in which the first electrodes are located away from the array substrate, the isolation structure is located on a side of the pixel defining layer away from the array substrate, and the pixel defining layers comprise pixel openings each exposing at least a part of the first electrode; and
orthographic projections of the pixel openings on the array are within orthographic projections of the plurality of isolation openings on the array substrate.

13. The display panel according to claim 11, wherein the display panel further comprises a first encapsulation layer, a second encapsulation layer, and a third encapsulation layer sequentially stacked on a sides of the light-emitting units away from the array substrate;
the first encapsulation layer extends into the recess;
a material of each of the first encapsulation layer and the third encapsulation layer comprises an inorganic material;
a material of the second encapsulation layer comprises an organic material;
the second electrode is electrically connected to the conductive portion;
the first electrode comprises an anode; and
the second electrode comprises a cathode.

14. The display panel according to claim 13, wherein the first encapsulation layer comprises a plurality of encapsulation units spaced apart, at least a part of the encapsulation units extending from a side of the isolation structure facing the plurality of isolation openings to a side of the isolation structure away from the array substrate;
at least two encapsulation units of the plurality of encapsulation units are spaced apart on the side of the isolation structure away from the array substrate; and
gaps are provided between the encapsulation units on the side of the isolation structure away from the array substrate and the side of the isolation structure away from the array substrate.

15. The display panel according to claim 14, wherein a plurality of encapsulation units for at least a part of the plurality of light-emitting units are continuously disposed on a side of the isolation structure away from the array substrate;
at least two encapsulation units for the at least two light-emitting units of the same emitting color are continuously disposed on the side of the isolation structure away from the array substrate;
at least two encapsulation units for at least two light-emitting units of different emitting colors are spaced apart on the side of the isolation structure away from the array substrate;
the light-emitting functional layers and the second electrodes are also located between the first encapsulation layer or the light-emitting units of the same emitting color and the side of the isolation structure away from the array substrate;
the light-emitting functional layers located between the first encapsulation layer and the side of the isolation structure away from the array substrate are spaced apart from the light-emitting functional layers located within the isolation openings, and
the second electrodes located between the first encapsulation layer and the side of the isolation structure away from the array substrate are spaced apart from the second electrodes located within the isolation openings.

16. The display panel according to claim 13, further comprising a filter layer on the side of the first encapsulation layer away from the array substrate, wherein the filter layer comprises a plurality of filtering portions, orthographic projections of the plurality of filtering portions on the array substrate covering orthographic projections of at least part of the light-emitting units on the array substrate;
each of the plurality of filtering portions has the same transmitting color as the emitting color of the corresponding light-emitting unit; and
the filter layer further comprises a shielding portion, the shielding portion being spaced apart from the plurality of filtering portions.

17. The display panel according to claim 16, wherein the isolation structure acts as the shielding portion, or the shielding portion is located on sides of the isolation structure away from the array substrate, and orthographic projection of the shielding portion on the array substrate are located within an orthographic projection of the isolation structure on the array substrate.

18. The display panel according to claim 1, wherein the display panel further comprises a plurality of touch electrodes disposed in the same layer as the isolation structure, the plurality of touch electrodes being insulated from the isolation structure; or the display panel further comprises touch layers on a side of the isolation structure away from the array substrate, the touch layers each comprising touch traces;
the display panel comprises a hole area and an active area at least partially surrounding the hole area, and the isolation structures also enclose a plurality of light-transmitting openings, the plurality of light-transmitting openings being located in the hole area, and
orthographic projections of the plurality of light-transmitting openings on the array substrate are located outside orthographic projections of the plurality of isolation openings on the array substrate.

19. A method for preparing a display panel, the method comprising:
providing an array substrate; and
forming an isolation structure on a side of the array substrate, the isolation structure enclosing a plurality of isolation openings, and the isolation structure comprising a conductive portion and an isolation portion which are sequentially stacked in a direction away from the array substrate, and the isolation portion comprising a recess that is recessed in a direction away from an isolation opening of the plurality of isolation openings.

20. (canceled)
